(19) United States
(12) Patent Application Publication
(10) Pub. No.: US 2021/0365188 A1
(43) Pub. Date: Nov. 25, 2021

(54) SORT IN MEMORY

(71) Applicant: Micron Technology, Inc., Boise, ID (US)

(72) Inventors: Harold Robert G. Trout, Boise, ID (US); Glen E. Hush, Boise, ID (US); Troy A. Manning, Meridian, ID (US); Timothy P. Finkbeiner, Boise, ID (US); Troy D. Larsen, Meridian, ID (US)

(21) Appl. No.: 17/324,170

(22) Filed: May 19, 2021

Related U.S. Application Data
(60) Provisional application No. 63/027,430, filed on May 20, 2020.

(51) Int. Cl. G06F 3/06

(52) U.S. Cl. CPC G06F 3/0611; G06F 3/0688; G06F 3/0659; G06F 3/0605

(57) ABSTRACT

The present disclosure includes systems, apparatuses and methods related to maintaining data in a sorted order in a memory array to improve access time to data in the memory array and directing access to a row of data in cache based upon an address associated with the data. In a number of embodiments, data stored in tables in sorted order can allow access to data based on upon the keys and/or the sorted order of the data, which can increase access times to data the memory array.

### PRIORITY INFORMATION

This application claims priority of U.S. Provisional Application Ser. No. 63/027,430, filed on May 20, 2020, the contents of which are incorporated herein by reference.

### TECHNICAL FIELD

The present disclosure relates generally to semiconductor memory and methods, and more particularly, to apparatuses and methods related to sort in memory.

### BACKGROUND

Memory devices are typically provided as internal, semiconductor, integrated circuits in computing systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, and resistance variable memory such as phase change random access memory (PCRAM), resistive random access memory (RRAM), and magnetoresistive random access memory (MRAM), such as spin torque transfer random access memory (STT RAM), among others.

Computing systems often include a number of processing resources (e.g., one or more processors), which may retrieve and execute instructions and store the results of the executed instructions to a suitable location. A processing resource can comprise a number of functional units such as arithmetic logic unit (ALU) circuitry, floating point unit (FPU) circuitry, and a combinatorial logic block, for example, which can be used to execute instructions by performing logical operations such as AND, OR, NOT, NAND, NOR, and XOR, and invert (e.g., inversion) logical operations on data (e.g., one or more operands). For example, functional unit circuitry may be used to perform arithmetic operations such as addition, subtraction, multiplication, and division on operands via a number of logical operations.

A number of components in a computing system may be involved in providing instructions to the functional unit circuitry for execution. The instructions may be executed, for instance, by a processing resource such as a controller and/or host processor. Data (e.g., the operands on which the instructions will be executed) may be stored in a memory array that is accessible by the functional unit circuitry. The instructions and data may be retrieved from the memory array and sequenced and/or buffered before the functional unit circuitry begins to execute instructions on the data. Furthermore, as different types of operations may be executed in one or multiple clock cycles through the functional unit circuitry, intermediate results of the instructions and data may also be sequenced and/or buffered.

### BRIEF DESCRIPTION OF THE DRAWINGS

FIG. 1 is a block diagram including a host coupled to a system configured to process and store data in accordance with a number of embodiments of the present disclosure.

FIG. 2 is a block diagram of a memory array in accordance with a number of embodiments of the present disclosure.

FIGS. 3A-3C include a block diagram of a memory array performing a write operation with sort in accordance with a number of embodiments of the present disclosure.

FIGS. 4A-4B include a block diagram of a memory array performing a read operation based on the sorted order of the key and address pairs in accordance with a number of embodiments of the present disclosure.

FIGS. 5A-5B include a block diagram of a memory array performing a read operation based on the key of the key and address pairs in accordance with a number of embodiments of the present disclosure.

FIGS. 6A-6B include a block diagram of a memory array performing a split operation on a row of an index table row in accordance with a number of embodiments of the present disclosure.

FIGS. 7A-7B are flow diagrams of methods for sort operations in accordance with a number of embodiments of the present disclosure.

FIGS. 8A-8B are flow diagrams of methods for write and read operations with sort in accordance with a number of embodiments of the present disclosure.

FIGS. 9A-9B are flow diagrams of methods for splitting a table in accordance with a number of embodiments of the present disclosure.

### DETAILED DESCRIPTION

The present disclosure includes systems, apparatuses and methods related to maintaining data in a sorted order in a memory array to improve access time to data in the memory array and to directing access to a row of data in cache based upon an address associated with the data. In a number of embodiments, data stored in tables in sorted order can allow access to data based on upon the keys and/or the sorted order of the data, which can increase access times to data the memory array. In a number of embodiments, a content addressable memory (CAM) can be configured to receive an address and perform a look up operation for the address in CAM and open a row in memory (e.g., cache) in response to locating the address in CAM during the look up operation. The look up operation can locate the address in a row of the CAM that is directly coupled to the row in memory and CAM can be configured to open a row in memory that is coupled to the row in the CAM where the address is located. The CAM can be configured to map a received virtual address of a main memory directly to a corresponding select line of the memory.

A memory can comprise a semiconductor material configured to store an electrical charge. However, such a semiconductor material may have slow switching capabilities. As such, a different semiconductor material having faster switching capabilities, but does not store an electrical charge well, may be used for logic circuitry coupled to the memory. Although a semiconductor material used for memory may have slow switching capabilities, the semiconductor material used for memory can have advantages over semiconductor materials having faster switching capabilities. These advantages can include, but are not limited to, a high degree of parallelism, closeness to data, and power efficiency.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure. As used herein, designators such as “n, “N,” etc., particularly with respect to reference numerals in the drawings, indicate that a number of the particular feature so designated can be included. As used herein, “a number of” a particular thing refers to one or more of such things (e.g., a number of memory arrays can refer to one or more memory arrays). A “plurality of” is intended to refer to more than one of such things.

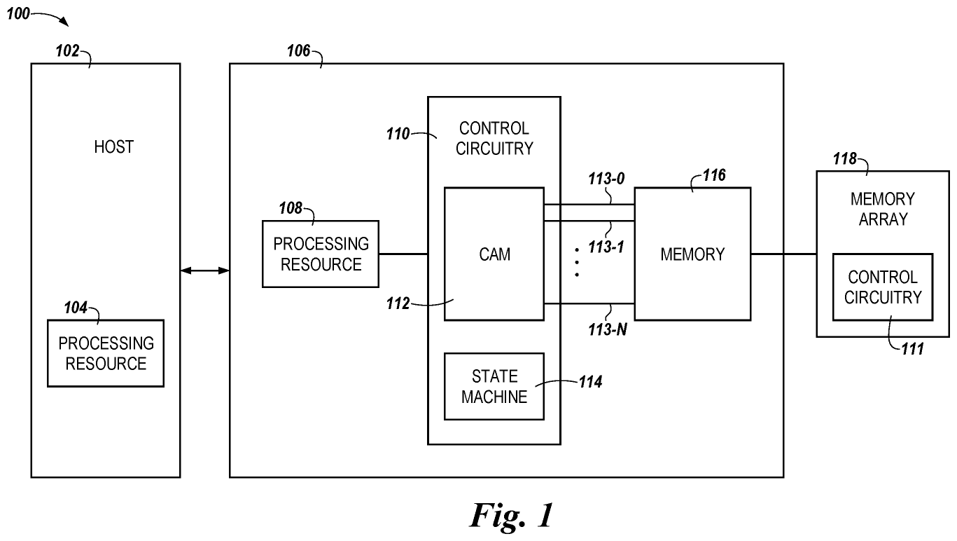

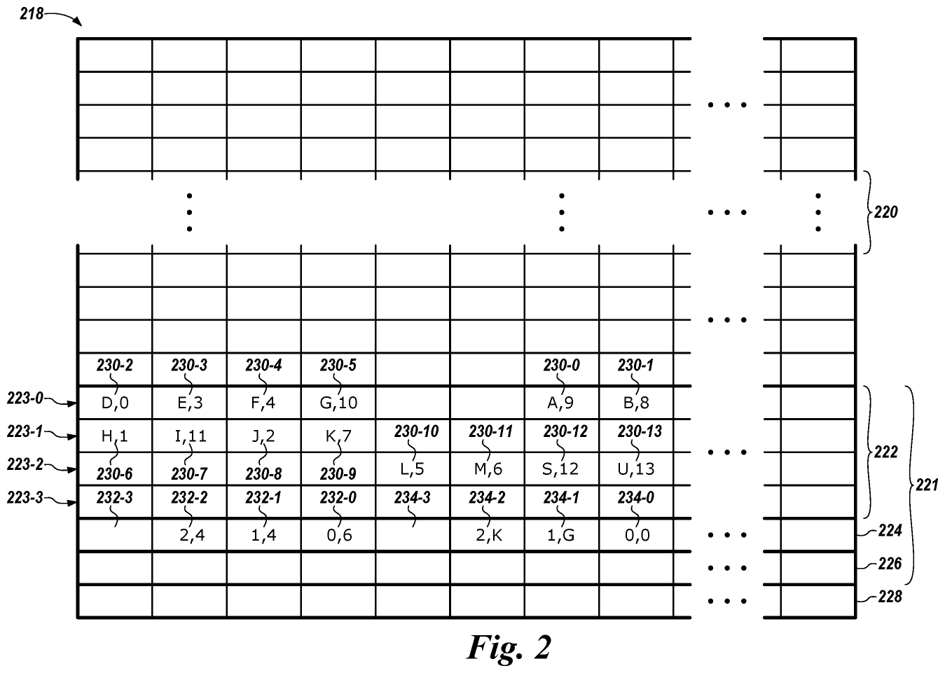

The figures herein follow a numbering convention in which the first digit or digits correspond to the drawing figure number and the remaining digits identify an element or component in the drawing. Similar elements or components between different figures may be identified by the use of similar digits. For example, 102 may reference element “02” in FIG. 1, and a similar element may be referenced as 202 in FIG. 2. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention, and should not be taken in a limiting sense.

FIG. 1 is a block diagram including a host 102 coupled to a system 100 configured to process and store data in accordance with a number of embodiments of the present disclosure. System 100 can include an apparatus 106 coupled to the host and configured to process data using processing resource 108 and memory 116. Processing resource 108 can be a RISC-V processor, for example. System 100 can also include apparatus 106 coupled to memory array 118. Memory array 118 can provide main memory for system 100 and can also provide storage as a backing store for system 100.

Memory array 118 can include control circuitry 111 configured to maintain data stored in tables in memory array 118 in sorted order. The sorted order can be based on keys associated with the data stored in memory array 118. The data stored in tables in sorted order can allow access to data based on upon the keys and/or the sorted order of the data, which can increase access times to data the memory array.

Apparatus 106 can include control circuitry 110 configured to directly map an address received from processing resource 108 and/or host 102 to a row in memory 116. Control circuitry 110 can include CAM 112 that is configured to receive an address and perform a look up operation for the address in CAM 112 and open a row in memory 116 in response to locating the address in CAM 112 in the look up operation. The look up operation can locate the address in a row of the CAM 112 that is directly coupled to the row in memory 116 and CAM 112 can be configured to open a row in memory 116 that is coupled to the row in the CAM 112 where the address is located.

The control circuitry 110 can be coupled to the memory 116. The memory 116 can be coupled to the memory array 118. The control circuitry 110 can include a CAM 112. In at least one embodiment, the CAM 112 can be on chip with the processing resource 108 and the memory 116. In at least one embodiment, the control circuitry 110 can include a state machine 114 (e.g., a finite state machine (FSM)) in communication with the CAM 112. The state machine 114 can generate operation codes (hereinafter referred to as “opcodes”) and provide opcodes to the CAM 112. The opcodes can control operations performed by the CAM 112 described herein, such as a lookup operation. The CAM 112 can be coupled to the memory 116. A single select line of the CAM 112 can be coupled to a single select line of the memory 116 as represented by lines 113-0, 113-1, . . . , 113-N. In at least one embodiment, the memory 116 can be SRAM. However, embodiments of the present disclosure are not so limited.

CAM 112 can be configured concurrently map a received virtual address of the memory array 118 to a corresponding physical address of the memory array 118, map the corresponding physical address of the memory array 118 to a corresponding physical address of the memory 116, and map the corresponding physical address of the memory 116 to a corresponding select line of the memory 116. The CAM 112 can serve as a decoder for the memory 116.

Apparatus 106 can be configured to intercept the virtual address sent to memory array 118 from the host 102 and/or the processing resource 104. The CAM 112 can be configured to determine whether a first portion of rows of memory cells of the CAM 112 stores the intercepted virtual address and determine whether the second portion of the rows of memory cells of the CAM stores the physical address of the memory.

FIG. 2 is a block diagram of a memory array 218 in accordance with a number of embodiments of the present disclosure. The memory array 218 can include a data portion 220 to store data received from a host, processing resource, and/or another memory device or array, among other sources. The memory array 218 can include a sort portion 221 that includes index table 222, key table 224, and logic stripe 226. The sort portion 221 can be configured to store keys and addresses associated with the data stored in data portion 220 in a sorted order. Keys and addresses can be represented by one or more bits that that written to and stored in sort portion 221. The sorted order can be sorted based upon the keys associated with the data in data portion 220. The data in data portion can be comprised on one or more bits, such as a string of bits. A requesting device, such as a host, processing resource, and/or another memory device or array, can access the data based upon the sorted order of the keys associated with the data in data portion 220.

Sort portion 221 can sort and store data associated with the data in data portion 220 using index table 222, key table 224, and logic stripe 226. Index table can include storing a key associated with a portion of data (e.g., a page of data) in data portion 220. For example, index table 222 can include index table rows 223-0, 223-1, 223-2, and 223-3 that are configured to store a particular number of entries each storing a key and an address associated with portion of data (e.g., a page) in data portion 220. In FIG. 2, index table rows 223-0, 223-1, 223-2, and 223-3 of index table 222 are configured to store 8 key and address pairs in each row and sort the key and address pairs within the 32 entries of index table rows 223-0, 223-1, 223-2, and 223-3. Each key and address pair includes a key (e.g., E) and an address (e.g., 3). The key is associated with a portion of data stored in data portion 220 and the address is the location in data portion 220 where the portion of data is stored. Index tables can include any number of index table rows and columns to store key and address pair entries.

Index table row 223-0 includes 6 key and address pair entries: A, 9 230-0; B, 8 230-1; D, 0 220-2; E, 3 230-3; F, 4 230-4; and G, 10 230-5. Index table row 223-1 includes 4 key and address pair entries: H, 1 230-6; I, 11 230-7; J, 2 230-8; and K, 7 23-9. Index table row 223-2 includes 4 key and address pair entries: L, 5 230-10, M, 6 230-11; S, 12 230-12; and U, 13 230-13. Each of the key and address pairs 230-0, . . . 230-13 are in sorted order based on alphabetical order of the keys. Key and address pairs can be sorted based upon any criteria than can be applied to the keys. For example, the keys can be numeric and can be sorted from low to high or from high to low.

In FIG. 2, key table 224 can include information about the key and address pairs stored in index table rows 223-0, 223-1, 223-2, and 223-3. Key table 224 can in an entry for each row of the index table rows that indicates a quantity of entries in the index table row. For example, 0, 6 in key table entry 232-0 indicates that index table row 223-0 has 6 key and address pairs, 1, 4 in key table entry 232-1 indicates that index table row 223-1 has 4 key and address pairs, and 2, 4 in key table entry 232-2 indicates that index table row 223-2 has 4 key and address pairs. Key table entry 232-3 is empty because key table row 223-3 does not have any key and address pairs.

Key table 224 can in an entry for each row of the index table rows that an indicator of the last key stored in each particular row or an adjacent row. Indicators can be comprised of one or more bits. For example, 0,0 in key table entry 234-0 indicates that index table row 223-0 has the first key and address pair for this sorted group, 1, G in key table entry 234-1 indicates that index table row 223-1 includes key and address pairs with keys above G, and 2, K in key table entry 234-2 indicates that index table row 223-2 includes key and address pairs with keys above K. Key table entry 234-3 is empty because key table row 223-3 does not have any key and address pairs.

Sort portion 221 includes logic stripe 226 that can include circuitry to compare incoming key and address pairs to the information in index table 224 and key table 224 to determine where in the sorted order a key and address pair will be placed in index table 222 or where a request for data using a key or sorted order position is located in data portion 220. Logic stripe 226 can include circuitry to shift key and address pairs along the logic stripe so the key and address pairs are maintained in sorted order and stored in a new location in index table 222 when a new key and address pair is added to index table 222.

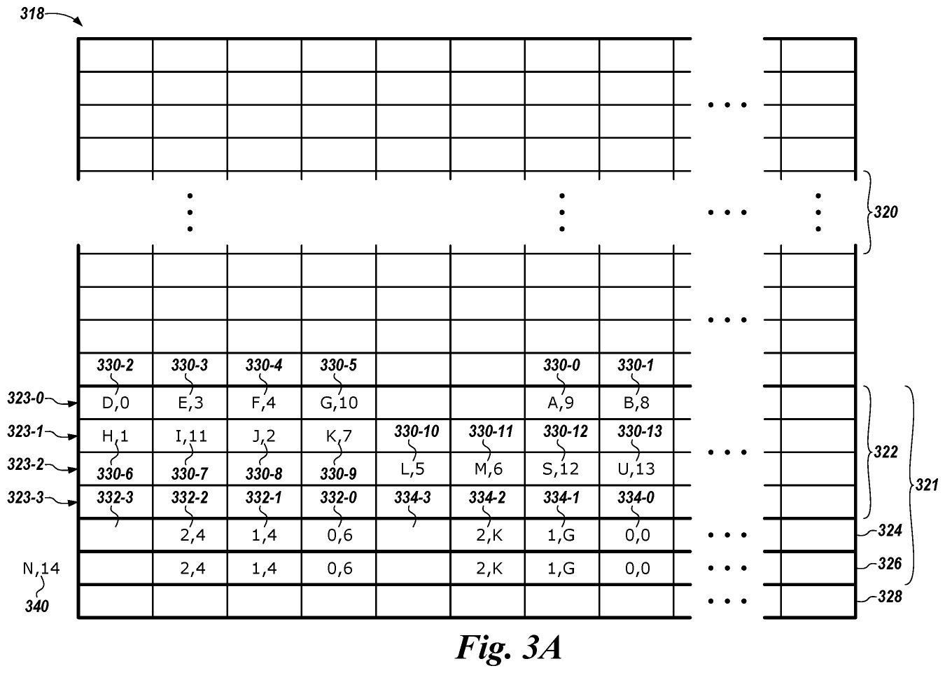

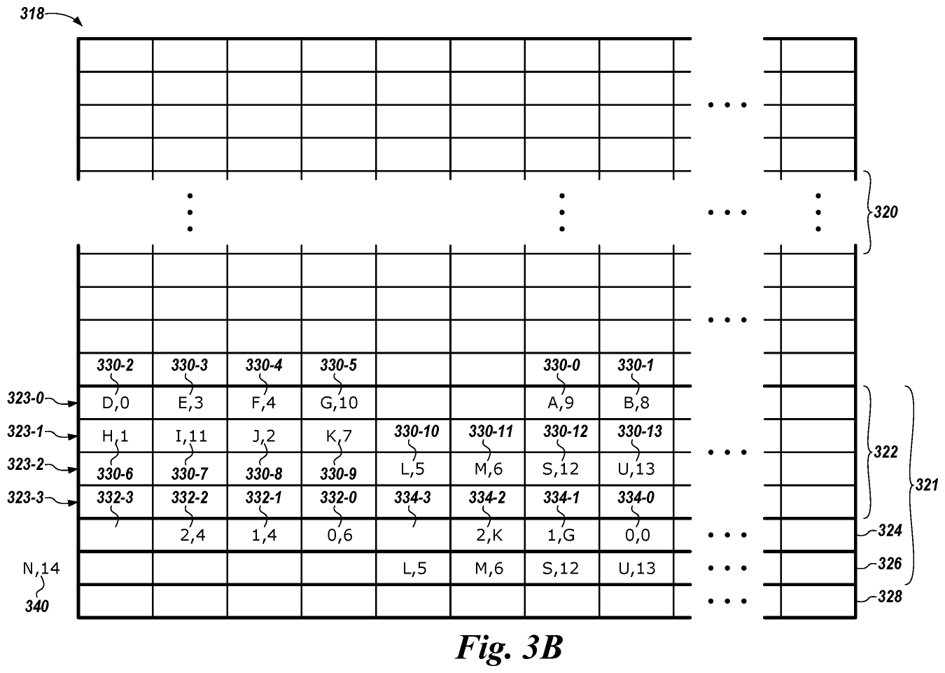

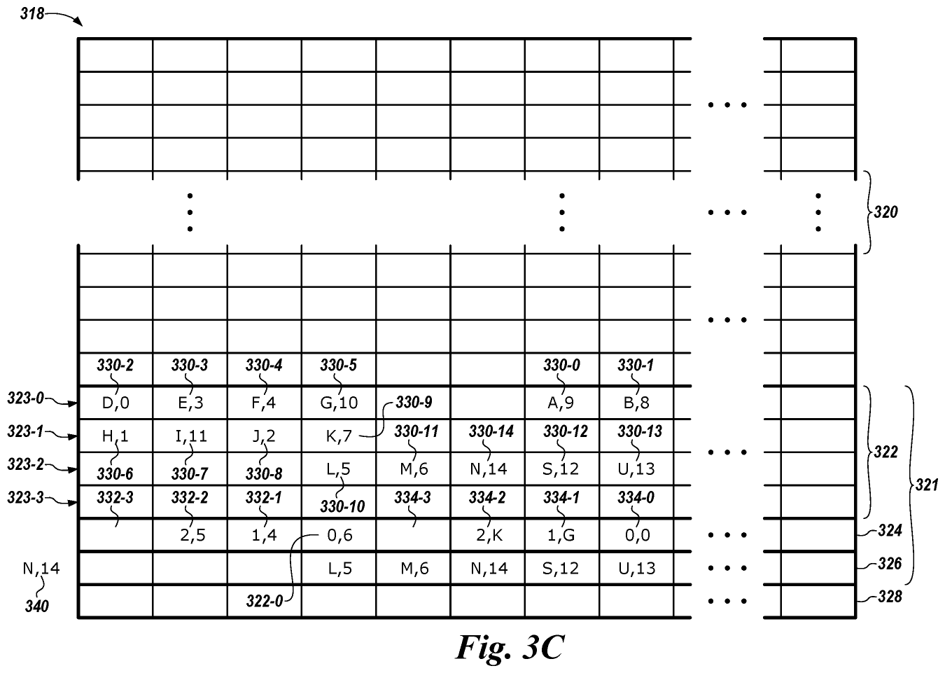

FIGS. 3A-3C include a block diagram of a memory array 318 performing a write operation with sort in accordance with a number of embodiments of the present disclosure. Sort portion 321 can sort and store data associated with the data in data portion 320 using index table 322, key table 324, and logic stripe 326. Index table can include storing a key associated with a portion of data (e.g., a page of data) in data portion 320.

Prior to a write operation, index table row 323-0 includes 6 key and address pair entries: A, 9 330-0; B, 8 330-1; D, 0 320-2; E, 3 330-3; F, 4 330-4; and G, 10 330-5. Index table row 323-1 includes 4 key and address pair entries: H, 1 330-6; I, 11 330-7; J, 2 330-8; and K, 7 330-9. Index table row 323-2 includes 4 key and address pair entries: L, 5 330-10, M, 6 330-11; S, 12 330-12; and U, 13 330-13. Each of the key and address pairs 330-0, . . . 330-13 are in sorted order based on alphabetical order of the keys. Key and address pairs can be sorted based upon any criteria than can be applied to the keys. For example, the keys can be numeric and can be sorted from low to high or from high to low.

A write operation can include writing data to data portion 320 with a key of N at address 14. Key and address pair 340, N, 14, associated with the data of a write operation is ready to be sorted and inserted into index table 322 while the data from the write operation is written to data portion 320 of memory array 318. Key and address pair 340 can be sorted by writing the key table information, entries 332-0, 332-1, 332-2, 334-0, 334-1, and 334-2 to logic stripe 326, as shown in FIG. 3A. Logic stripe 326 can be configured to determine which index table row to insert key and address pair 240 based on entries 334-0, 334-1, and 334-2. Logic stripe 326 can determine that key and address pair 340 will be placed in index table row 323-2 in response to the entry 334-2 indicating that index table row can receive keys above K and with an upper bound, due to there not being any key and address pairs in index table rows after index table row 323-2. Logic stripe 326 can be configured to determine which index table row to place incoming key and address pairs based on bins defined by the information in key table 324. For example, information in key table 324 can identify the highest key and address pair based on the sorted order for the prior index table row.

In response to logic stripe 326 determining that key and address pair 340 will be placed in index table row 323-2, the data from index table row 323-2 can be stored in logic stripe 326. Key and address pair entries: L, 5 330-10, M, 6 330-11; S, 12 330-12; and U, 13 330-13 from index table row 323-2 can be placed in logic stripe 326, as shown in FIG. 3B. Logic stripe 326 can determine that key and address pair 340 with key N will be placed in index table row 323-2 between key and address pair 330-11 with key M and key and address pair 330-12 with key S. To place key and address pair 430 between key and address pairs 330-11 and 330-12, logic stripe 326 can be configured to shift key and address pairs 330-10 and 330-11 to left one entry to open space for key and address pair 340 in the sorted order, as shown in FIG. 3C.

Key and address pair 340 can be placed between shifted key and address pair 330-11 and key and address pair 330-12 in logic stripe 326. The key and address pairs in the updated sorted order to include key and address pair 340 can be written back to index table row 323-2 in the updated sorted order, such that index table row 323-2 includes key and address pairs, 330-10, 330-11, 330-14, 330-12, and 330-13 in sorted order, as shown in FIG. 3C. Key table 324 can be updated to indicate any changes in the quantity of entries in the index table rows or the highest key that is included in each of the index table rows. In FIG. 3C, key table 324 can be updated to indicate that index table row 323-2 has 5 entries with key table entry 332-2 having an indicator of 2, 5.

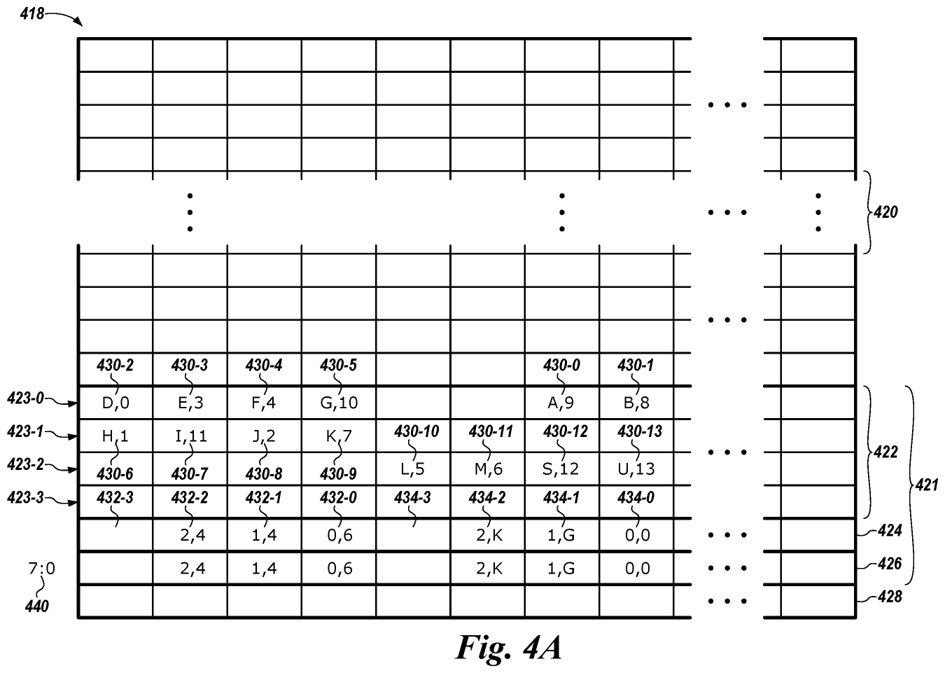

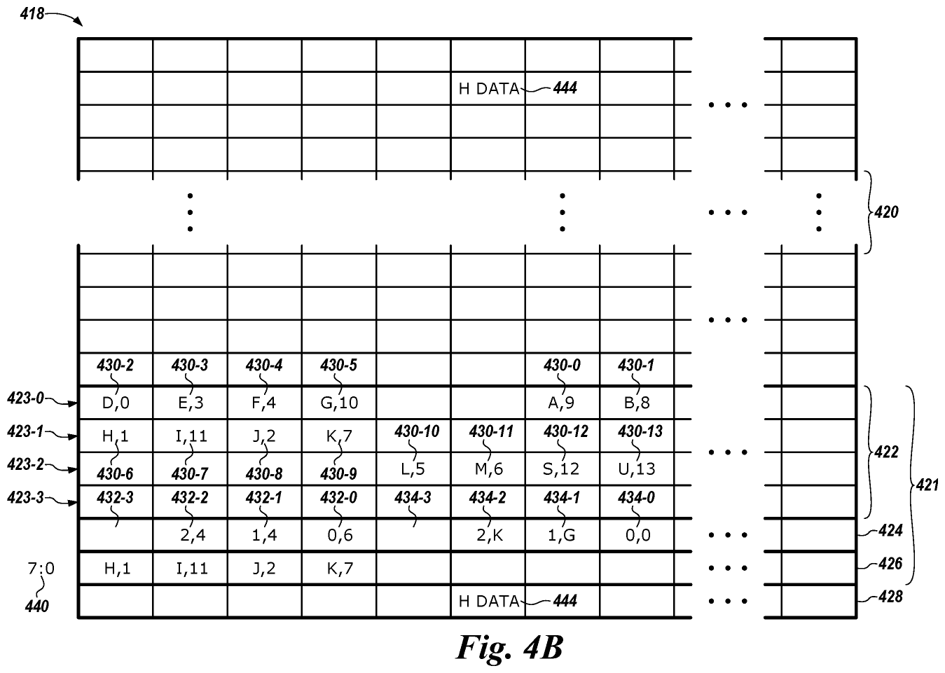

FIGS. 4A-4B include a block diagram of a memory array 418 performing a read operation based on the sorted order of the key and address pairs in accordance with a number of embodiments of the present disclosure. Sort portion 421 can sort and store data associated with the data in data portion 420 using index table 422, key table 424, and logic stripe 426. Index table can include storing a key associated with a portion of data (e.g., a page of data) in data portion 420.

Index table row 423-0 includes 6 key and address pair entries: A, 9 430-0; B, 8 430-1; D, 0 430-2; E, 3 430-3; F, 4 430-4; and G, 10 430-5. Index table row 423-1 includes 4 key and address pair entries: H, 1 430-6; I, 11 430-7; J, 2 430-8; and K, 7 430-9. Index table row 423-2 includes 4 key and address pair entries: L, 5 430-10, M, 6 430-11; S, 12 430-12; and U, 13 430-13. Each of the key and address pairs 430-0, . . . 430-13 are in sorted order based on alphabetical order of the keys. Key and address pairs can be sorted based upon any criteria than can be applied to the keys. For example, the keys can be numeric and can be sorted from low to high or from high to low.

A read operation can include reading data from data portion 420 using the address portion of a key and address pair that is located in index table 422 according to embodiments of the present disclosure. An incoming read request can include an indication that data associated with the 7^{th} key and address pair in the sorted order of index table 422 is requested. Logic stripe 426 can be configured to determine where the 7^{th} key and address pair in the sorted order of index table 422 is located based on entries 434-0, 434-1, and 434-2 in key table 426, which can be placed in logic strip 426. Logic stripe 426 can determine that the 7^{th} key and address pair in the sorted order of index table 422 in response to the entry 432-0 indicating that index table row 423-0 has 6 entries and index table row 423-1 has 4 entries, therefore the 7^{th} key and address pair in the sorted order of index table 422 is located in index table row 423-1. Logic stripe 426 can be configured to determine that the 7^{th} key and address pair in the sorted order of index table 422 is the first key and address pair of index table row 423-1 by subtracting the total number of entries in the table index rows prior to the table index row where the requested key and address pair is located. In FIG. 4A, the first key and address pair of index table row 423-1 is entry 430-6, H, 1.

The information of key and address pair entries 430-6, 430-7, 430-8, and 430-9 from table index row 423-1 can be placed in logic stripe 426. Logic stripe 426 can be configured to locate the data associated with the request in data portion 420 based on the address of key and address pair 430-1, which includes data associated with key H located at address 1 in data portion 420. The data associated with key H can be read and placed in sense amp stripe 428 and then sent from the memory array to fulfill the read request.

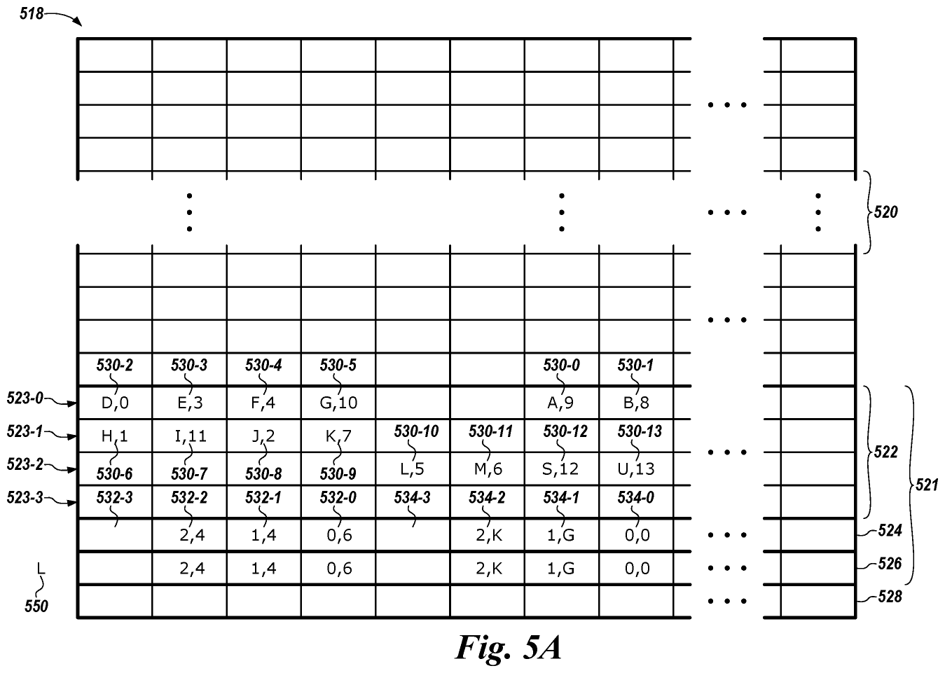

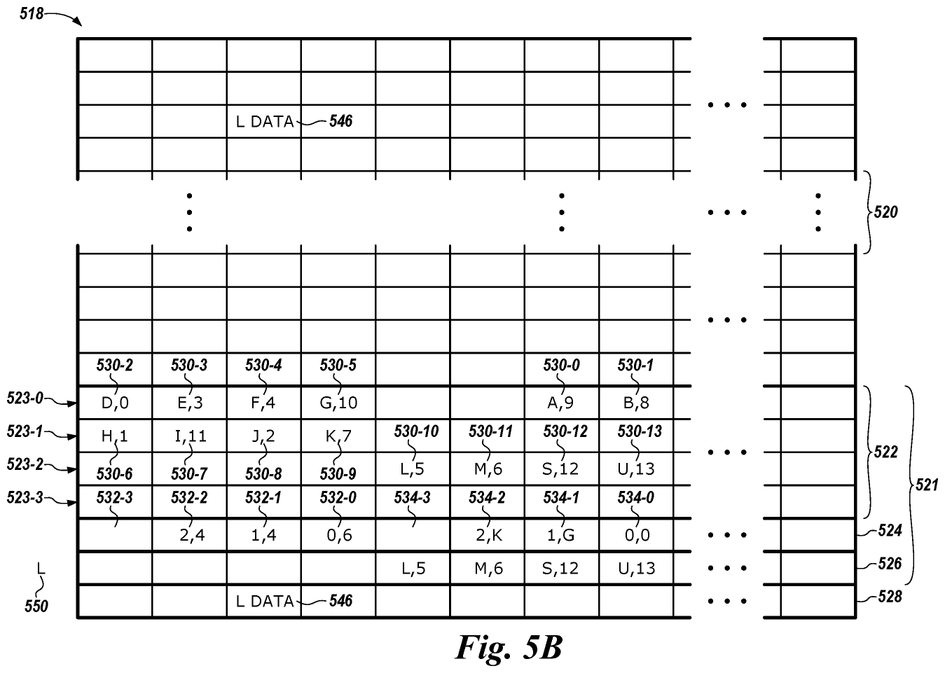

FIGS. 5A-5B include a block diagram of a memory array 518 performing a read operation based on the key of the key and address pairs in accordance with a number of embodiments of the present disclosure. Sort portion 521 can sort and store data associated with the data in data portion 520 using index table 522, key table 524, and logic stripe 526. Index table can include storing a key associated with a portion of data (e.g., a page of data) in data portion 520.

Index table row 523-0 includes 6 key and address pair entries: A, 9 530-0; B, 8 530-1; D, 0 530-2; E, 3 530-3; F, 4 530-4; and G, 10 530-5. Index table row 523-1 includes 4 key and address pair entries: H, 1 530-6; I, 11 530-7; J, 2 530-8; and K, 7 530-9. Index table row 523-2 includes 4 key and address pair entries: L, 5 530-10, M, 6 530-11; S, 12 530-12; and U, 13 530-13. Each of the key and address pairs 530-0, . . . 530-13 are in sorted order based on alphabetical order of the keys. Key and address pairs can be sorted based upon any criteria than can be applied to the keys. For example, the keys can be numeric and can be sorted from low to high or from high to low.

A read operation can include reading data from data portion 520 using the address portion of a key and address pair that is located in index table 522 according to embodiments of the present disclosure. An incoming read request can include an indication that data associated with a key of a key and address pair in the sorted order of index table 522 is requested. Logic stripe 526 can be configured to determine where key L of request 550 is located in the sorted order of index table 522. Logic stripe 526 can located key L located based on entries 534-0, 534-1, and 534-2 in key table 526, which can be placed in logic strip 526. Logic stripe 526 can determine that key L in the sorted order of index table 522 is in index table row 523-2 in response to the entry 532-2 indicating that index table row 523-2 has entries with keys above key K, therefore key L in the sorted order of index table 522 is located in index table row 523-2.

The information of key and address pair entries 530-10, 530-11, 530-12, and 530-13 from table index row 523-2 can be placed in logic stripe 526. Logic stripe 526 can be configured to locate the data associated with the request in data portion 520 based on the address of key L in key and address pair 530-10, which includes data associated with key L located at address 5 in data portion 520. The data associated with key L can be read and placed in sense amp stripe 528 and then sent from the memory array to fulfill the read request.

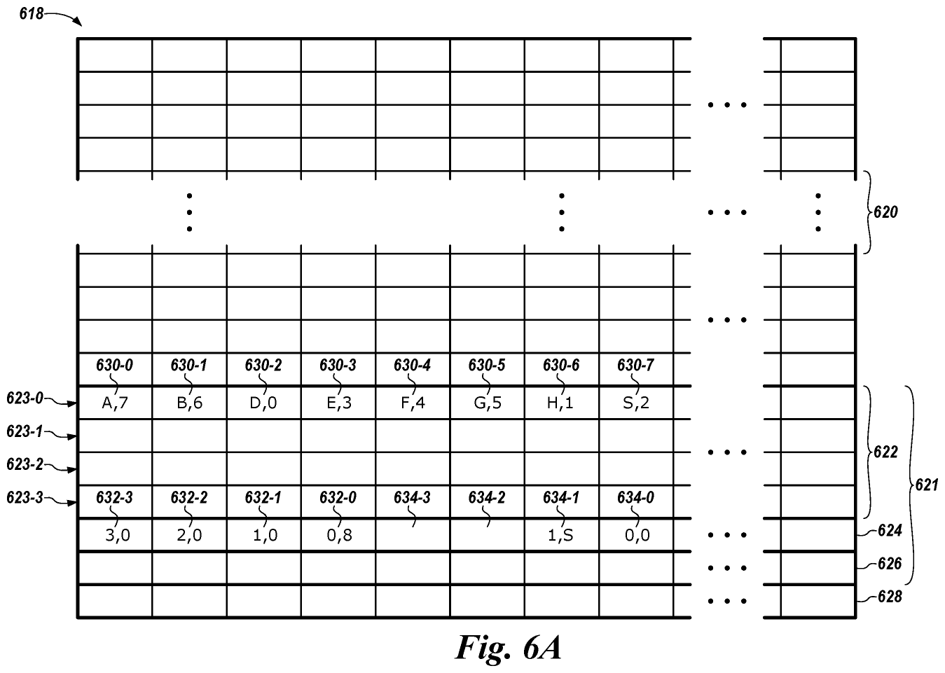

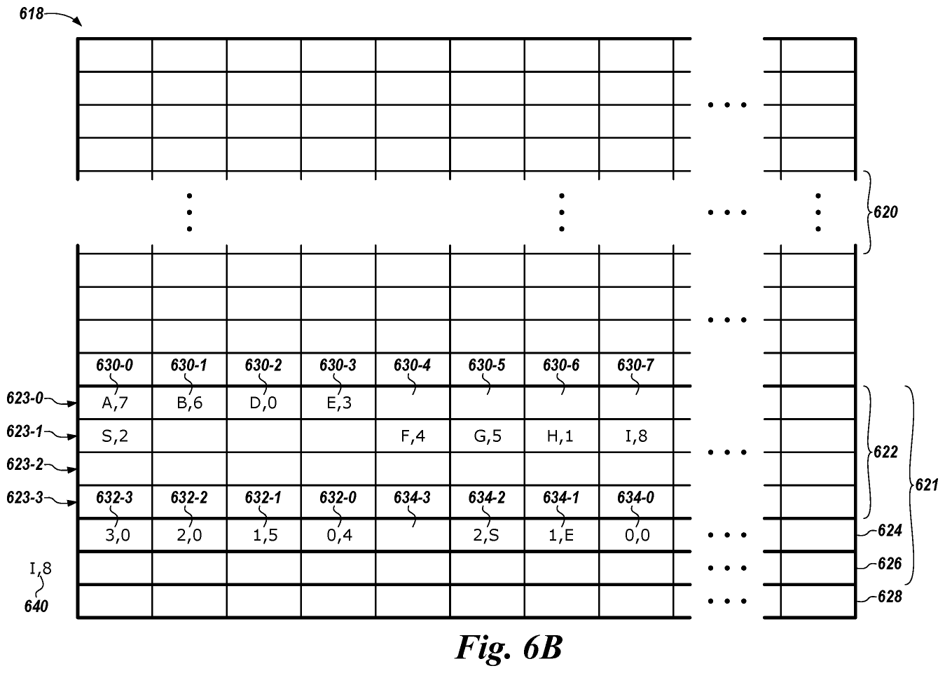

FIGS. 6A-6B include a block diagram of a memory array 618 performing a split operation on a row of an index table row in accordance with a number of embodiments of the present disclosure. Sort portion 621 can sort and store data associated with the data in data portion 620 using index table 622, key table 624, and logic stripe 626. Index table can include storing a key associated with a portion of data (e.g., a page of data) in data portion 620.

Index table row 623-0 includes 8 key and address pair entries: A, 7 630-0; B, 6 630-1; D, 0 630-2; E, 3 630-3; F, 4 630-4; G, 5 630-5; H, 1 630-6; and S, 2 630-7. Each of the key and address pairs 630-0, . . . 630-7 are in sorted order based on alphabetical order of the keys. Key and address pairs can be sorted based upon any criteria than can be applied to the keys. For example, the keys can be numeric and can be sorted from low to high or from high to low.

A write operation can include writing data to data portion 620 and writing a key and address pair associated with the data to the index table 622. When writing a key and address pair to a full index table row, the full index table row can be split between two rows to maintain the sorted order. An incoming write request can include an indication that data associated with a key of a key and address pair in the sorted order of index table 622 will be placed in a full index table row. The full index table row can be split by copying the entries in the full index table row to another row. The originally full row can be updated to include half of the entries in the full row and the row where the entries were copied can be updated to include the other of the entries in the full row.

In FIG. 6B, entries 630-0, . . . , 630-7 can be copied from index table row 623-0 to index table row 623-1. Entries 630-0, . . . , 630-7 can be split where 630-0, . . . 630-3 will remain in sorted order in index tale row 623-0 and entries 630-4, . . . , 630-7 will be in sorted order index table row 623-2. Index table row 630-1 can be folded row as a result of the split, where the lowest key in folded row starts at the beginning of the second half of the row, at entry 630-4.

Key and address pair 640, I, 8 associated with the write operation can then be placed in index table 622. Key and address pair 640 can be placed in index table in response to logic stripe 626 determining that key and address pair 640 should be located between key and address pairs 630-6 and 630-7 and shifting key and address pair 630-7 to make room for key and address pair 640, as shown in FIG. 6B.

Key table 624 can be updated to indicate any changes in the quantity of entries in the index table rows or the highest key that is included in each of the index table rows that resulted from the split. In FIG. 6B, key table 624 can be updated to indicate that index table row 623-0 has 4 entries with key table entry 632-0 having an indicator of 0, 0 and index table row 623-1 has 5 entries with key table entry 632-0 having an indicator of 1, E.

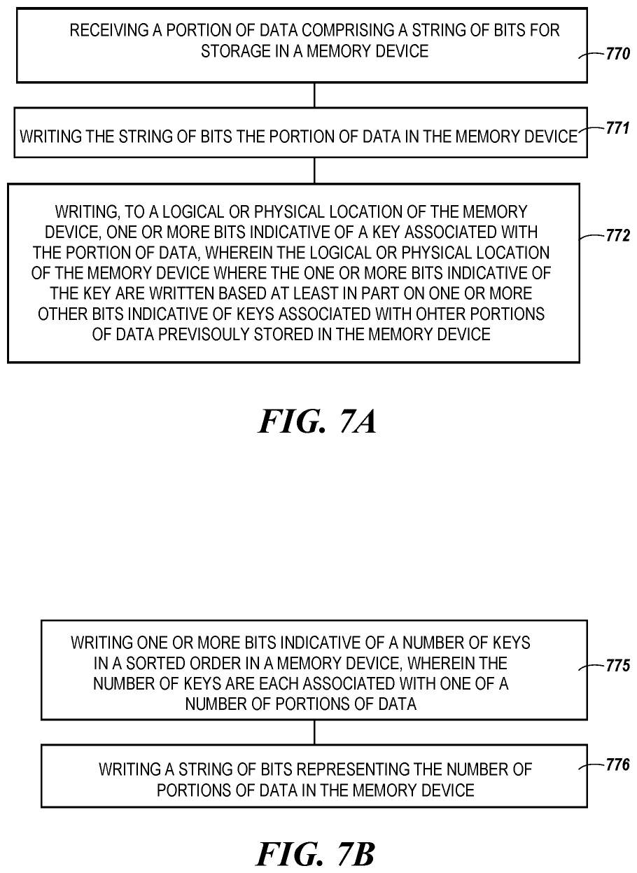

FIGS. 7A and 7B are flow diagrams of methods for sort operations in accordance with a number of embodiments of the present disclosure. In FIG. 7A, at block 770, the method can include receiving a portion of data comprising a string of bits for storage in a memory device. At block 771, the method can include writing the string of bits of the portion of data in the memory device. At block 772, the method can include writing, to a logic or physical location of the memory device, one or more bits indicative of a key associated with the portion of data, wherein the logical or physical location of the memory device where the one or more bits indicative of the key are written based at least in part on one or more other bits indicative of keys associated with other portions of data previously stored in the memory device. The key associated with the portion of data can be stored in a sorted order in the memory device, wherein the sorted order is in relation to keys associated with portions of data previously stored in the memory device. In a number of embodiments, storing the key occurs while storing the portion of data in the memory device, therefore sorting the keys associated with the data in sorted order does not add additional overhead or increase latency of write operations.

A number of embodiments can include storing an address associated with the data along with the key, as key and address pairs. The key and address pairs can be stored in an index table in the memory device. Storing the key associated with the portion of data in the sorted order includes comparing the key to the key associated with the portions of data previously stored in the memory device.

A number of embodiments can include accessing the portion of data based on the key associated with the portion of data and/or accessing the portion of data based on a position in the sorted order of the key associated with the portion of data.

In FIG. 7B, at block 775, the method can include writing one or more bits indicative of a number of keys in a sorted order in a memory device, wherein the number of keys are each associated with one of a number of portions of data. At block 776, the method can include writing a string of bits representing the number of portions of data in the memory device. The method can include storing a particular number of keys per row in the memory device and maintaining the number of keys in sorted order in response to receiving an additional key to add to the number of keys stored in the memory device by shifting positions in the sorted order of a portion of the number of keys.

In a number of embodiments, the key table can be used for storing an indicator of a quantity of keys that are stored in each particular row and an indicator of the last key stored in each particular row.

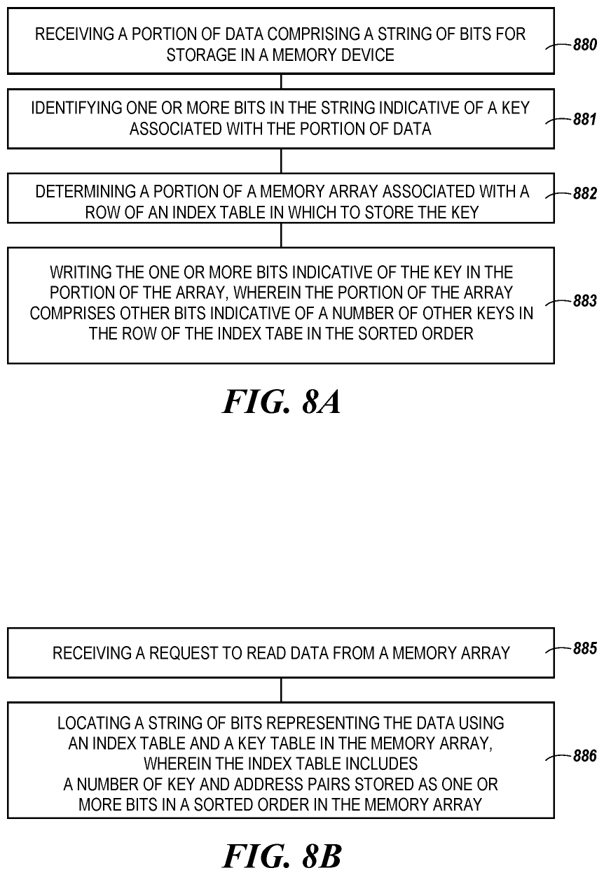

FIGS. 8A and 8B are flow diagrams of methods for write and read operations with sort in accordance with a number of embodiments of the present disclosure. In FIG. 8A, at block 880, the method can include receiving a portion of data comprising a string of bits for storage in a memory device. At block 881, the method can include identifying one or more bits in the string indicative of a key associated with the portion of data. At block 882, the method can include determining a portion of a memory array associated with a row of an index table in which to store the key, wherein the row of the index table is based at least in part on a sorted order of the key and other keys associated with portions of data previously stored in the more device. At block 883, the method can include writing the one or more bits indicative of the key in the portion of the array, wherein the portion of the array comprises other bits indicative of a number of other keys in the row of the index table in the sorted order.

In a number of embodiments, writing the one or more bits indicative of in the row of the index table in the sorted order can include storing the number of keys in the row of the index table in a logic stripe, comparing the key to the number of keys in the row of the index table using a logic stripe, shifting a portion the number of keys in the row of the index table to new locations in a logic stripe, writing the one or more bits indicative of the key in an open position of a logic stripe that resulted from shifting a portion the number of keys in the row of the index table to new locations in the logic stripe, and/or writing the key and the number of keys in sorted order from a logic stripe to the row of the index table.

In FIG. 8B, at block 885, a method can include receiving a request to read data from a memory array. At block 886, a method can include locating a string of bits representing the data using an index table and a key table in the memory array, wherein the index table includes a number of key and address pairs stored as one or more bits in a sorted order in the memory array. The request to read data can include a key associated with the data.

The method can include locating a row in the index table where one or more bits indicative of the key are located based on comparing the key and the key table that includes in indication of the last key stored in each particular row of the index table, reading the key and address pair from the row in the index table, and/or locating the data in the memory array based on an address of the key and address pair associated the requested data. The request to read data can include an indication of a position in the sorted order of a key associated with the data.

The method can include locating a row in the index table where one or more bits indicative of a key and address pair associated with the data is located based on an indication of a quantity of keys stored in each particular row and/or locating one or more bits indicative of the key and address pair associated with the data based on subtracting a quantity of key and address pairs stored in rows of the index table above the row of the index table from an indication of a position in the sorted order of a key associated with the data.

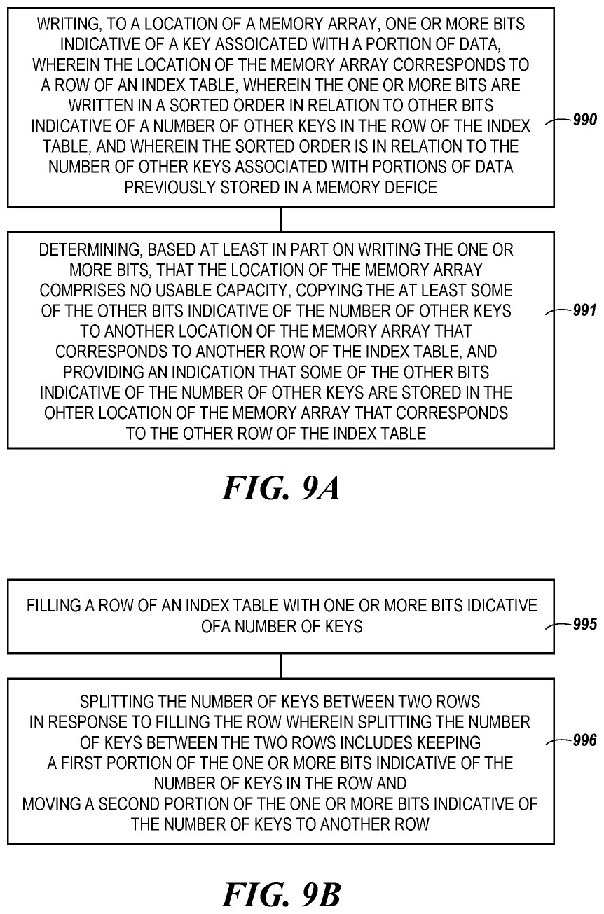

FIGS. 9A and 9B are flow diagrams of methods for splitting a table in accordance with a number of embodiments of the present disclosure. In FIG. 9A, at block 990, the method can include writing, to a location of a memory array, one or more bits indicative of a key associated with a portion of data, wherein the location of the memory array corresponds to a row of an index table, wherein the one or more bits are written in in a sorted order in relation to other bits indicative of a number of other keys in the row of the index table, and wherein the sorted order is in relation to the number of other keys associated with portions of data previously stored in a memory device. At block 991, the method can include determining, based at least in part on writing the one or more bits, that the location of the memory array comprises no usable capacity, copying the at least some of the other bits indicative of the number of other keys to another location of the memory array that corresponds to another row of the index table, and providing an indication that some of the other bits indicative of the number of others keys are stored in the other location of the memory array that corresponds to the other row of the index table.

The method can include providing an indication that the sorted order of the some of the other bits indicative of the number of other keys begins at a particular location in the index table, storing one or more bits indicative of a new key in the row at a location where some of the other bits indicative of the number of other keys were located, storing one or more bits indicative of a new key in the another row, and/or maintaining the sorted order when storing one or more bits indicative of the number of keys in two rows.

In FIG. 9B, at block 995, the method can include filling a row of an index table with one or more bits indicative of a number of keys. At block 996, the method can include splitting the number of keys between two rows in response to filling the row, wherein splitting the number of keys between the two rows includes keeping a first portion of the one or more bits indicative of the number of keys in the row and moving a second portion of the one or more bits indicative of the number of key to another row. In a number of embodiments, splitting the number of keys between two rows can include leaving the first portion of the one or more bits indicative of the number of keys in a first half of the row, moving the second portion of the one or more bits indicative of the number of keys to a second half of the another row, and/or maintaining a sorted order of the number of keys.

The method can include updating a key table that includes an indication of a quantity of the first portion of the number of keys in the row and an indication of a quantity of the second portion of the number of keys in the another row. The method can include updating a key table that includes an indication of a last key of the first portion of the number of keys in the row and an indication of a last key of the second portion of the number of keys in the another row. The method can include proving an indication that a sorted order of the another row begins in the second half of the another row and splitting the second portion of number of keys between two rows in response to filling the another row.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and methods are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
receiving a portion of data comprising a string of bits for storage in a memory device;
writing the string of bits of the portion of data in the memory device; and
writing, to a logical or physical location of the memory device, one or more bits indicative of a key associated with the portion of data, wherein the logical or physical location of the memory device where the one or more bits indicative of the key are written based at least in part on one or more other bits indicative of keys associated with other portions of data previously stored in the memory device.

2. The method of claim 1, further comprising writing the one or more bits indicative of the key contemporaneously with writing the portion of data in the memory device.

3. The method of claim 1, further comprising writing additional bits that represent an address associated with the data contemporaneously with writing the one or more bits indicative of the key.

4. The method of claim 1, further comprising writing the one or more bits indicative of the key in a portion of the memory device that comprises an index table.

5. The method of claim 1, further comprising comparing the one or more bits indicative of the key to the other bits indicative of keys associated with the other portions of data previously stored in the memory device; and identifying the logical or physical location of the memory where the one or more bits are written based at least in part on the comparison.

6. The method of claim 1, further comprising receiving an access command that the portion of data; and reading the portion of data in response to the access command based at least in part on reading on the one or more bits indicative of the key associated with the portion of data.

7. The method of claim 1, further including accessing the portion of data based on a position of the key associated with the portion of data relative to the keys associated with other portions of data previously received.

8. A method, comprising:
writing one or bits indicative of a number of keys in a sorted order in a memory device, wherein the number of keys are each associated with one of a number of portions of data; and
writing a string of bits representing the number of portions of data in the memory device.

9. The method of claim 8, wherein writing the one or bits indicative of the number of keys includes storing a particular number of keys per row in the memory device.

10. The method of claim 8, further including storing an indicator, comprising one or more bits, of a quantity of keys that are stored in each particular row.

11. The method of claim 8, further including storing an indicator, comprising one or more bits, of the last key stored in each particular row.

12. The method of claim 10, further including storing the indicator of the quantity of keys that are stored in each particular row and storing an indicator, comprising one or more bits, of the last key stored in each particular row in a key table.

13. The method of claim 8, further including maintaining the number of keys in sorted order in response to receiving an additional key to add to the number of keys stored in the memory device.

14. The method of claim 13, wherein maintaining the number of keys in sorted order includes shifting positions in the sorted order of a portion of the number of keys.

15. An apparatus, comprising:
a memory array; and
control circuitry, coupled to the memory array, configured cause the apparatus to:
write one or more bits indicative of a number of key and address pairs of keys in a sorted order in a memory array, wherein the number of key and address pairs are associated with a number of portions of data comprising strings of bits; and
write the strings of bits of the number of portions of data in the memory array.

16. The apparatus of claim 15, wherein the number of key and address pairs are stored in an index table portion of the memory array.

17. The apparatus of claim 15, wherein the sorted order is based on the keys of the number of key and address pairs associated with the number of portions of data.

18. The apparatus of claim 15, wherein the control circuitry is configured to cause the apparatus to store an indicator, comprising one or more bits, of a quantity of keys that are stored in each particular row of the memory array.

19. The apparatus of claim 15, wherein the control circuitry is configured to cause the apparatus to store an indicator, comprising one or more bits, of a quantity of keys that are stored in each particular row of the memory array.

20. The apparatus of claim 15, wherein the control circuitry is configured to cause the apparatus to store a particular number of key and address pairs per row of the memory array.

21. An apparatus, comprising:
a memory array; and
a control circuitry, coupled to the memory array, configured cause the apparatus to:
access data stored in the memory array based on a number of key and address pairs of keys stored in a sorted order in the memory array, wherein the number of key and address pairs are associated with a number of portions of data stored in the memory array.

22. The apparatus of claim 21, wherein the control circuitry is configured cause the apparatus to access the data based on the key associated with the portion of data.

23. The apparatus of claim 21, wherein the control circuitry is configured cause the apparatus to access the data based on a position in the sorted order of the key associated with the data.

24. The apparatus of claim 21, wherein the address portion of the key and address pairs indicates a location in the memory array where the data is located.

25. The apparatus of claim 21, wherein the control circuitry is configured cause the apparatus to access the data based on a key table that indicates a row in the memory array where a key associated with the data is located.
